(19) United States
(12) Patent Application Publication
(10) Pub. No.: US 2014/0353601 A1
(43) Pub. Date: Dec. 4, 2014

(54) FILM FOR DISPLAY APPARATUS, ORGANIC LIGHT-EMITTING DISPLAY APPARATUS INCLUDING THE SAME, AND METHOD OF MANUFACTURING THE FILM

(71) Applicant: Samsung Display Co., Ltd., Yongin-City (KR)

(72) Inventors: Kwan-Hyun CHO, Yongin-City (KR); Jin-Koo CHUNG, Yongin-City (KR)

(73) Assignee: Samsung Display Co., Ltd., Yongin-City (KR)

(21) Appl. No.: 14/046,054

(22) Filed: Oct. 4, 2013

(30) Foreign Application Priority Data
May 29, 2013 (KR) 10-2013-0061256

(51) Int. Cl. H01L 51/52

(52) U.S. Cl. CPC H01L 51/5271
USPC 257/40; 428/192

(57) ABSTRACT

A film for a display apparatus includes a first thin film including at least one of an organic material and an inorganic material, a metal thin film in contact with a first portion of a surface of the first thin film, and a second thin film in contact with a second portion of the surface of the first thin film, which is different from the first portion.

This application claims priority to Korean Patent Application No. 10-2013-0061256, filed on May 29, 2013, and all the benefits accruing therefrom under 35 U.S.C. §119, the content of which in its entirety is herein incorporated by reference.

### BACKGROUND

1. Field

Exemplary embodiments of the invention relate to a film for a display apparatus, an organic light-emitting display apparatus including the film, and a method of manufacturing the film for a display apparatus.

2. Description of the Related Art

A display apparatus is an apparatus used for providing visual information, such as images or pictures, to a user. The display apparatus may be configured in various forms to display the visual information, such as images or pictures.

In particular, an organic light-emitting display apparatus is a self light-emitting type of display apparatus that electrically excites an organic compound therein to emit light. Since the organic light-emitting display apparatus may be operated at a low voltage, may be efficiently provided in a thin profile, and may have wide viewing angles and fast response speeds.

However, when such an organic light-emitting display apparatus is employed in a transparent display, the interconnection resistance of a common electrode that covers the entire pixels of the organic light-emitting display apparatus may increase.

### SUMMARY

Exemplary embodiments of the invention relate to a film for a display apparatus having a low reflectance in a portion that displays an image and having high transmittance in remaining portions.

Exemplary embodiments of the invention relate to an organic light-emitting apparatus including the film for a display apparatus, and a method of manufacturing the film for a display apparatus.

According to an exemplary embodiment of the invention, there is provided a film for a display apparatus including: a first thin film including at least one of an organic material and an inorganic material; a metal thin film in contact with a first portion of a surface of the first thin film; and a second thin film in contact with a second portion of the surface of the first thin film, which is different from the first portion.

In an exemplary embodiment, adhesion between the metal thin film and the second thin film may be lower than adhesion between the metal thin film and the first thin film.

In an exemplary embodiment, the film for a display apparatus may further include a plurality of unit films stacked on one another, where each of the unit films includes the first thin film, the metal thin film and the second thin film.

In an exemplary embodiment, the metal thin film may include at least one of magnesium and silver.

In an exemplary embodiment, the second thin film may include at least one of 8-quinolinolato lithium,
N,N-diphenyl-N,N-bis(9-phenyl-9H-carbazol-3-yl)biphenyl-4,4′-diamine,
N(diphenyl-4-yl)9,9-dimethyl-N-(4(9-phenyl-9H-carbazol-3-yl)phenyl)-9H-fluorene-2-amine, and
2-(4-(9,10-di(naphthalene-2-yl)anthracene-2-yl)phenyl)-1-phenyl-1H-benzo-[D]imidazole.

In an exemplary embodiment, a thickness of the metal thin film may be less than a wavelength in a wavelength range of visible light.

In an exemplary embodiment, the thickness of the metal thin film may be in a range of about 5 nanometers (nm) to about 500 nanometers (nm).

In an exemplary embodiment, a thickness of the first thin film may be smaller than about 10 times a wavelength in the wavelength range of visible light.

In an exemplary embodiment, the thickness of the first thin film may be in a range of about 10 nm to about 5,000 nm.

In an exemplary embodiment, light reflectance of a portion, in which the first thin film and the metal thin film overlap each other, may be lower than light reflectance of a portion in which the first thin film and the second thin film overlap each other.

In an exemplary embodiment, light transmittance of the portion, in which the first thin film and the second thin film overlap each other, may be higher than light transmittance of the portion in which the first thin film and the metal thin film overlap each other.

In an exemplary embodiment, the metal thin film may be disposed in a center portion of the first thin film.

In an exemplary embodiment, the film for a display apparatus may further include a third thin film disposed on the metal thin film and the second thin film.

According to another exemplary embodiment of the invention, an organic light-emitting display apparatus includes: a substrate; an organic light-emitting unit disposed on the substrate; and a film disposed on the substrate, where the film includes a first thin film including at least one of an organic material and an inorganic material, a metal thin film in contact with a first portion of a surface of the first thin film, and a second thin film in contact with a second portion of the surface of the first thin film, which is different from the first portion.

In an exemplary embodiment, adhesion between the metal thin film and the second thin film may be lower than adhesion between the metal thin film and the first thin film

In an exemplary embodiment, the film may include a plurality of unit films stacked on one another, where each of the unit films may include the first thin film, the metal thin film and the second thin film.

In an exemplary embodiment, the metal thin film may include at least one of magnesium and silver.

In an exemplary embodiment, the second thin film may include at least one of 8-quinolinolato lithium,
N,N-diphenyl-N,N-bis(9-phenyl-9H-carbazol-3-yl)biphenyl-4,4′-diamine,
N(diphenyl-4-yl)9,9-dimethyl-N-(4(9-phenyl-9H-carbazol-3-yl)phenyl)-9H-fluorene-2-amine, and
2-(4-(9,10-di(naphthalene-2-yl)anthracene-2-yl)phenyl)-1-phenyl-1H-benzo-[D]imidazole.

In an exemplary embodiment, a thickness of the metal thin film may be less than a wavelength in a wavelength range of visible light.

In an exemplary embodiment, light reflectance of a portion, in which the first thin film and the metal thin film overlap each other, may be lower than light reflectance of a portion, in which the first thin film and the second thin film overlap each other.

In an exemplary embodiment, light transmittance of the portion, in which the first thin film and the second thin film overlap each other, may be higher than light transmittance of the portion in which the first thin film and the metal thin film overlap each other.

In an exemplary embodiment, the organic light-emitting unit may include a pixel electrode, an intermediate layer including an organic light-emitting layer, and a counter electrode.

In an exemplary embodiment, the metal thin film may overlap the organic light-emitting layer.

According to another exemplary embodiment of the invention, a method of manufacturing a film for a display apparatus includes: providing a first thin film; providing a metal thin film on a first portion of a surface of the first thin film; and providing a second thin film on a second portion of the surface of the first thin film, which is different from a first portion.

### BRIEF DESCRIPTION OF THE DRAWINGS

The above and other features of the invention will become more apparent by describing in detail exemplary embodiments thereof with reference to the attached drawings in which:

FIG. 1 is a schematic exploded perspective view of an exemplary embodiment of a film for a display apparatus, according to the invention;

FIGS. 2A through 2C are reference views illustrating an exemplary embodiment of a method of manufacturing a film for a display apparatus, according to the invention;

FIG. 3 is a cross-sectional view of an exemplary embodiment of an organic light-emitting display apparatus according to the invention;

FIG. 4 is a plan view schematically illustrating an exemplary embodiment of an organic light-emitting unit of an organic light-emitting display apparatus according to the invention;

FIG. 5 is a schematic view illustrating an interconnection structure of an exemplary embodiment of a pixel block of FIG. 4;

FIG. 6 is a circuit diagram illustrating an exemplary embodiment of a pixel of FIG. 5;

FIG. 7 is a cross-sectional view schematically illustrating a portion of a pixel of the organic light-emitting unit of FIG. 4; and

FIG. 8 is a schematic exploded perspective view of an alternative exemplary embodiment of a film for a display apparatus, according to the invention.

### DETAILED DESCRIPTION

The invention will be described more fully hereinafter with reference to the accompanying drawings, in which embodiments of the invention are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims set forth herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, exemplary embodiments of the invention will be described with reference to the accompanying drawings.

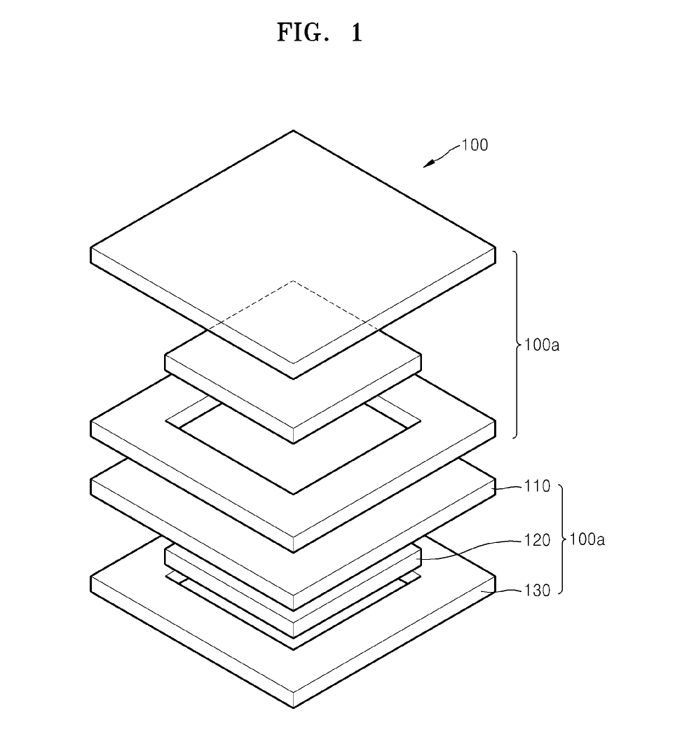

FIG. 1 is a schematic exploded perspective view of an exemplary embodiment a film 100 for a display apparatus, according to the invention. Referring to FIG. 1, the film 100 for a display apparatus includes a first thin film 110 including at least one of an organic material and an inorganic material, a metal thin film 120 disposed on a surface the first thin film 110 (e.g., a lower surface), and a second thin film 130 disposed on the surface of the first thin film 100. In such an embodiment, the surface of the first thin film 110 may include a first portion and a second portion, which are different from each other, the metal thin film 120 may be in contact with a first portion of the surface of the first thin film 110, and the second thin film 130 may be in contact with the second portion of the surface of the first thin film 110.

The first thin film 110 may include a specific dopant material such that the metal thin film 120 may be effectively disposed, e.g., deposited, thereon. In one exemplary embodiment, for example, the specific dopant material may be Di-tungsten tetra(hexahydropyrimidopyrimidine). In an exemplary embodiment, the first thin film 110 may have a structure, in which an organic material and an inorganic material are alternatingly deposited, but the invention is not limited thereto. In an exemplary embodiment, a thickness of the first thin film 110 may be less than about 10 times a wavelength in a wavelength range of visible light. In one exemplary embodiment, for example, the thickness of the first thin film 110 may be in a range of about 10 nanometers (nm) to about 5,000 nanometers (nm).

In an exemplary embodiment, the first portion may be a center portion of the surface of the first thin film 110, and the metal thin film 120 may be in contact with the center portion of the surface of the first thin film 110. The metal thin film 120 may include a metal, such as silver (Ag), magnesium (Mg), aluminum (Al), platinum (Pt), palladium (Pd), gold (Au), nickel (Ni), neodymium (Nd), iridium (Ir), chromium (Cr), lithium (Li), or calcium (Ca), for example. A thickness of the metal thin film 120 may be less than a wavelength in the wavelength range of visible light. In one exemplary embodiment, for example, the thickness of the metal thin film 120 may be in a range of about 5 nm to about 500 nm.

The second thin film 130 may be in contact with the second portion, a portion of the surface of the first thin film 110, on which the metal thin film 120 is not disposed, e.g., a peripheral portion of the surface of the first thin film 110. The second thin film 130 may include a material having low adhesion to the metal thin film 120. In such an embodiment, adhesion between the metal thin film 120 and the second thin film 130 may be lower than adhesion between the metal thin film 120 and the first thin film 110. In one exemplary embodiment, for example, the second thin film 130 may include at least one of 8-quinolinolato lithium,
N,N-diphenyl-N,N-bis(9-phenyl-9H-carbazol-3-yl)biphenyl-4,4′-diamine,
N(diphenyl-4-yl)9,9-dimethyl-N-(4(9-phenyl-9H-carbazol-3-yl)phenyl)-9H-fluorene-2-amine, and
2-(4-(9,10-di(naphthalene-2-yl)anthracene-2-yl)phenyl)-1-phenyl-1H-benzo-[D]imidazole.

In such an embodiment, the second thin film 130 is disposed on the same layer as the metal thin film 120 (e.g., on the first thin film 110), and a thickness of the second thin film 130 may be substantially the same as a thickness of the metal thin film 120. In such an embodiment, the thickness of the second thin film 130 may be less than a wavelength in the wavelength range of visible light. In one exemplary embodiment, for example, the thickness of the second thin film 130 may be in a range of about 10 nanometers (nm) to about 5,000 nanometers (nm)

The first thin film 110, the metal thin film 120 and the second thin film 130 may collectively define a unit film 100a, and an exemplary embodiment of the film 100 for a display apparatus may include a plurality of unit films 100a, which are sequentially stacked on one another. In such an embodiment, the film 100 for a display apparatus may be provided by stacking the unit film 100a multiple times. In an exemplary embodiment, as shown in FIG. 1, the film 100 for a display apparatus may include two stacked unit films 100a, but the invention is not limited thereto. In an exemplary embodiment, two or more unit films 100a may be stacked in the film 100 for a display apparatus. In an exemplary embodiment, 10 or less unit films 100a may be stacked in the film 100 for a display apparatus to limit the thickness of the film 100. In an alternative exemplary embodiment, the film 100 for a display apparatus may include one or more unit film 100a and the first thin film 110, or may include one or more unit film 100a, the metal thin film 120 and the second thin film 130.

In an exemplary embodiment, the light reflectance of a first portion of the film 100 for a display apparatus, in which the first thin film 110 and the metal thin film 120 overlap, is relatively low, and the light transmittance of a second portion of the film 100 for a display apparatus, in which the first thin film 110 and the second thin film 130 overlap, is relatively high. In such an embodiment, the light reflectance of the first portion may be lower than that of the second portion, and the light transmittance of the second portion may be higher than that of the first portion. In such an embodiment, destructive interference may occur in waves incident on the first thin film 110 and the metal thin film 120, light absorption due to surface plasmon may occur at an interface between the metal thin film 120 and the first thin film 110, and light absorption of the first thin film 110 and the second thin film 130, which are transparent, is substantially low.

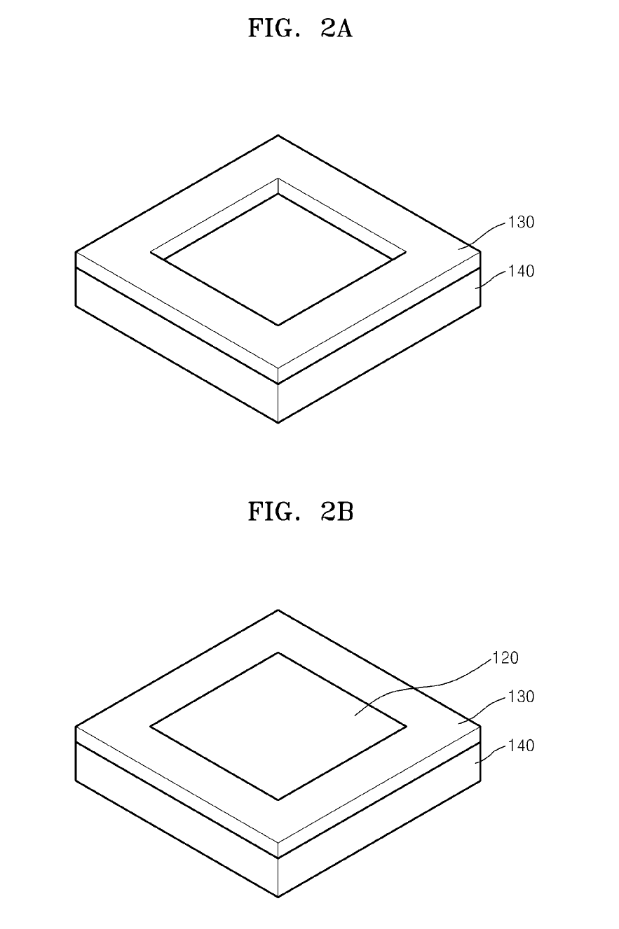

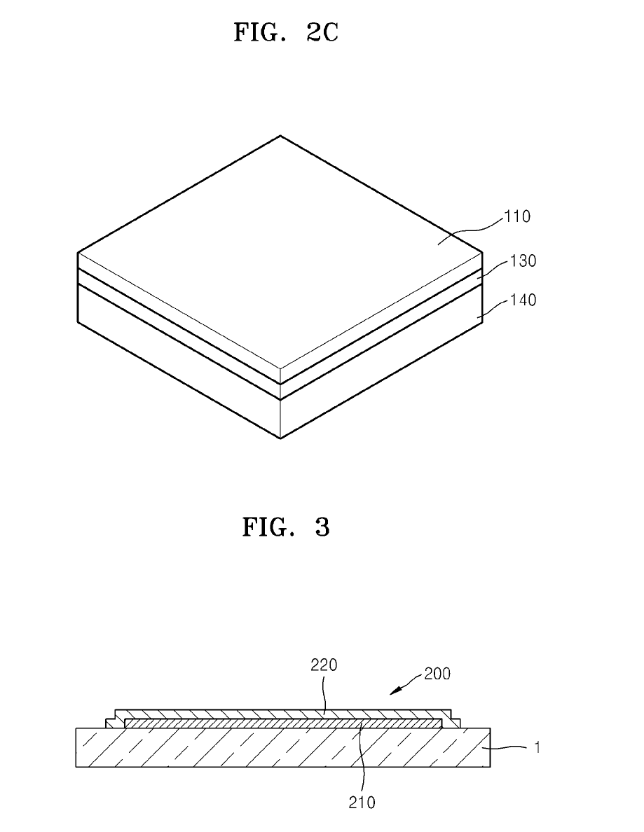

Next, an exemplary embodiment of a method of manufacturing the film 100 for a display apparatus will be described. FIGS. 2A through 2C are reference views illustrating an exemplary embodiment of a method of manufacturing the film 100 for a display apparatus, according to the invention.

First, a substrate 140 is prepared as illustrated in FIG. 2A. The substrate 140 may be a transparent substrate or a substrate in which an organic light-emitting unit of the display apparatus is disposed. An exemplary embodiment, where the substrate 140 is a substrate including the organic light-emitting unit thereon will be described later in detail. A second thin film 130 is provided on a portion of the substrate 140, e.g., a portion of the substrate 140 corresponding to the second portion of the lower surface of first thin film 110 to be provided. In one exemplary embodiment, for example, the second thin film 130, in which an opening is defined, may be patterned on the substrate 140 by depositing the second thin film 130 using a mask on the substrate 140. The second thin film 130 may include at least one of 8-quinolinolato lithium,
N,N-diphenyl-N,N-bis(9-phenyl-9H-carbazol-3-yl)biphenyl-4,4′-diamine,
N(di phenyl-4-yl)9,9-dimethyl-N-(4(9-phenyl-9H-carbazol-3-yl)phenyl)-9H-fluorene-2-amine, and
2-(4-(9,10-di(naphthalene-2-yl)anthracene-2-yl)phenyl)-1-phenyl-1H-benzo-[D]imidazole.

As illustrated in FIG. 2B, a metal thin film 120 is provided, e.g., formed, on the substrate 140. In an exemplary embodiment, a metallic material may be provided on substantially an entire of the substrate 140 by sputtering or vacuum thermal evaporation. In such an embodiment, the adhesion between the second thin film 130 and the metal thin film 120 is substantially low, such that the metal thin film 120 may be provided only in a portion in which the second thin film 130 is not formed, for example, a portion exposed by the opening of the second thin film 130. The metal thin film 120 may include a material having low adhesion to the second thin film 130.

In one exemplary embodiment, for example, the metal thin film 120 may include a metal, such as Ag, Mg, Al, Pt, Pd, Au, Ni, Nd, Ir, Cr, Li or Ca, for example. In one exemplary embodiment, for example, the metal thin film 120 may include Mg or an alloy of Mg and Ag.

As illustrated in FIG. 2C, a first thin film 110 is provided on the substrate 140. The first thin film 110 may be provided on the second thin film 130 and the metal thin film 120.

In FIGS. 2A to 2C, an exemplary embodiment of a method of manufacturing a single unit film 100a is described. However, the invention is not limited thereto. In an alternative exemplary embodiment, where the film 100 for a display apparatus includes a plurality of unit films 110a, the plurality of unit films 100a may be manufactured by repeatedly stacking the unit film 100a of FIGS. 2B and 2C.

In such an embodiment, the metal thin film 120 in a same layer as the second thin film 130 may be provided by self-patterning using the second thin film 130, the providing the metal thin film 120 and the second thin film 130 on the substrate 140 is substantially facilitated.

In an exemplary embodiment of a display apparatus including the film 100, the film 100 may perform a sealing function on the display apparatus. In an exemplary embodiment of a display apparatus including the film 100, the film 100 is disposed to allow the metal thin film 120 to overlap a display area of the display apparatus, in which an image is displayed, and to allow the second thin film 130 to overlap a non-display area of the display apparatus, in which an image is not displayed.

FIG. 3 is a cross-sectional view of an exemplary embodiment of an organic light-emitting display apparatus 200 according to the invention. Referring to FIG. 3, an exemplary embodiment of the organic light-emitting display apparatus 200 includes an organic light-emitting unit 210 disposed on a substrate 1 and a film 220 that covers the organic light-emitting unit 210. In such an embodiment, the film 220 may include the exemplary embodiment of the film 100 for a display apparatus described above.

The film 220 may be a transparent film, and thus, an image from the organic light-emitting unit 210 may be transmitted through the film 220, and the film 220 effectively prevents the penetration of outside air and moisture into the organic light-emitting unit 210.

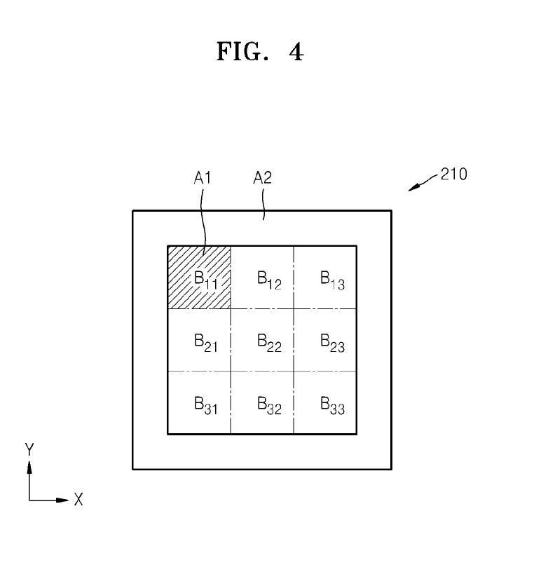

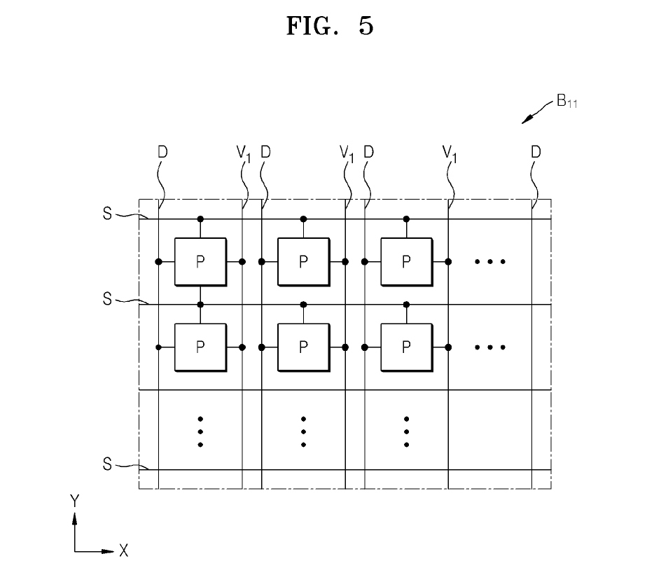

FIG. 4 is a plan view schematically illustrating an exemplary embodiment of an organic light-emitting unit 210 of an organic light-emitting display apparatus according to the invention, and FIG. 5 is a schematic view illustrating an interconnection structure of an exemplary embodiment a pixel block of FIG. 4.

Referring to FIGS. 4 and 5, in an exemplary embodiment of the organic light-emitting unit 210, a display area A1 and a non-display area A2 are defined on a substrate of the organic light-emitting unit 210.

The display area A1, in which an image is displayed, may be defined by a center portion of the substrate, and the non-display area A2 may be defined by a portion around the display area A1.

In such an embodiment, a plurality of pixels P, which displays an image, is included in the display area A1.

Each pixel P may be defined by a scan interconnection S extending substantially in a first direction X and a data interconnection D extending substantially in a second direction Y that is substantially perpendicular to the first direction X, but not being limited thereto. The data interconnection D applies a data signal provided by a data driver (not shown) disposed in the non-display area A2 to each pixel P, and the scan interconnection S applies a scan signal provided by a scan driver (not shown) disposed in the non-display area A2 to each pixel P. In an exemplary embodiment, as shown in FIG. 5, the data interconnection D extends in the second direction Y, and the scan interconnection S extends in the first direction X. However, the invention is not limited thereto. In an alternative exemplary embodiment, the extension directions of the data interconnection D and the scan interconnection S may be interchanged.

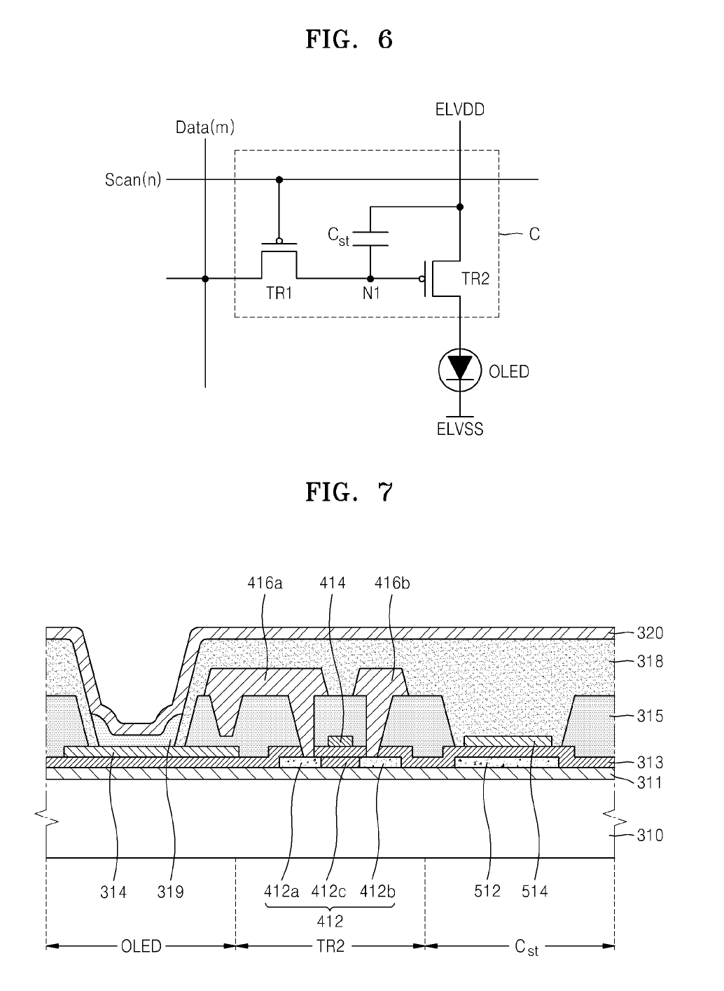

Each pixel P is connected to a first power supply line V1 extending substantially in the second direction Y. A first power ELVDD (see FIG. 6) provided by a first power driver (not shown) included in the non-display area A2 to each pixel P is applied via the first power supply line V1. Although not illustrated in FIG. 4, a second power ELVSS (see FIG. 6) is provided to each pixel P. Each pixel P controls an amount of current provided from the first power ELVDD to the second power ELVSS via an organic light-emitting device (“OLED”) (see FIG. 6) in response to the data signal. Then, light having a predetermined intensity is generated in the OLED.

In an exemplary embodiment, the first portion of the film 220 including the metal thin film therein is disposed to overlap the display area of the organic light-emitting unit, and the second portion of the film 220 including the second thin film therein is disposed to overlap the non-display area of the organic light-emitting unit. In such an embodiment, reflectance may be low when the light generated in the display area of the organic light-emitting unit passes through the first portion, such that the reduction of contrast and visibility of the light by the film 220 may be effectively prevented. In such an embodiment, the first thin film and the second thin film are stacked in an area other than the display area of the organic light-emitting unit, such that the organic light-emitting unit may be blocked from outside air, and a transparent display apparatus may also be realized.

FIG. 6 is a circuit diagram of an exemplary embodiment of a pixel of FIG. 5.

Referring to FIG. 6, the pixel includes an OLED and a pixel circuit C for providing current to the OLED.

A pixel electrode of the OLED is connected to the pixel circuit C and a counter electrode 320 is connected to the second power ELVSS. The OLED generates light having a predetermined intensity in response to the current provided from the pixel circuit C.

In an exemplary embodiment, the display apparatus may be an active matrix-type organic light-emitting display apparatus, and a pixel of the display apparatus may include a plurality of transistors and a capacitor (e.g., one or more capacitor). In an exemplary embodiment, as shown in FIG. 6, a pixel of the display apparatus may include a switching transistor for transferring a data signal, a driving transistor for driving the OLED, and a single capacitor for maintaining a data voltage. However, the number of thin film transistors and capacitors is not limited thereto, and more than two thin film transistors and more than one capacitor may be included in a pixel of an alternative exemplary embodiment of the display apparatus.

In an exemplary embodiment, as shown in FIG. 6, a gate electrode of a first transistor TR1 is connected to the scan interconnection S (see FIG. 5), a first electrode of the first transistor TR1 is connected to the data interconnection D (see FIG. 5), and a second electrode of the first transistor TR1 is connected to a first node N1. In such an embodiment, a scan signal (Scan (n)) is input to the gate electrode of the first transistor TR1 and a data signal (Data (m)) is input to the first electrode of the first transistor TR1.

A gate electrode of a second transistor TR2 is connected to the first node N1, a first electrode of the second transistor TR2 is connected to the first power ELVDD, and a second electrode of the second transistor TR2 is connected to the pixel electrode of the OLED. In such an embodiment, the second transistor TR2 functions as a driving transistor.

A first capacitor Cst is connected between the first node N1 and the first electrode of the second transistor TR2, i.e., the first power ELVDD.

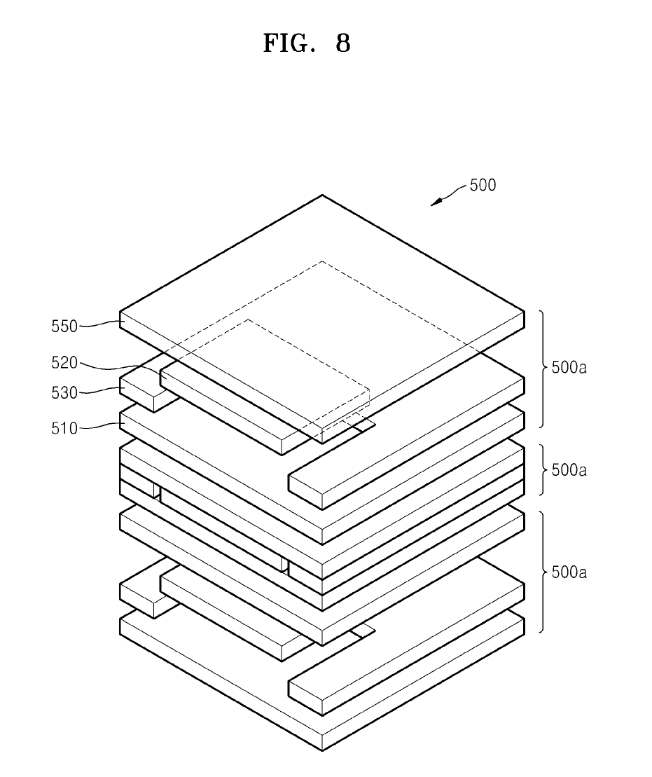

FIG. 7 is a cross-sectional view schematically illustrating a portion of a pixel of the organic light-emitting unit of FIG. 4.

Referring to FIG. 7, the second transistor TR2, which may function as a driving thin film transistor, the first capacitor Cₛₜ, and the OLED are disposed on a substrate 310.

In an exemplary embodiment, the substrate 310 may include a transparent glass material including SiO₂, for example, but not being limited thereto. In an alternative exemplary embodiment, the substrate 310 may include a transparent plastic material. The substrate 310 may be a flexible substrate having flexibility. The flexible substrate may include a material having characteristics of lightweight (e.g., a lower specific density than a glass substrate), high toughness and flexibility, for example, a polymer material, such as a flexible plastic film.

In an exemplary embodiment, a buffer layer 311 may be disposed on the substrate 310. In such an embodiment, the buffer layer 311 may include an inorganic material, such as SiOₓ, SiNₓ, SiON, AlO and AlON, for example, or an organic material, such as acryl and polyimide, for example. In an exemplary embodiment, or the buffer layer 311 may be provided by alternatingly stacking the organic material and the inorganic material. The buffer layer 311 blocks oxygen and moisture, effectively prevents the diffusion of moisture or impurities generated from the substrate 310, and controls a heat transfer rate during crystallization. In such an embodiment, the buffer layer 311 may facilitate the crystallization of a semiconductor.

In an exemplary embodiment, the second transistor TR2 is disposed on the buffer layer 311. In an exemplary embodiment, the second transistor TR2 may be a bottom gate type thin film transistor, as shown in FIG. 7, but not being limited thereto. In an alternative exemplary embodiment, a thin film transistor may have other structures, such as a top gate type, for example.

In such an embodiment, an active layer 412 is disposed on the buffer layer 311. In an exemplary embodiment, the active layer 412 may include polysilicon, and the active layer 412 may be provided by providing amorphous silicon and then transforming the amorphous silicon into polysilicon by crystallization.

In such an embodiment, various methods, such as rapid thermal annealing (“RTA”), solid phase crystallization (“SPC”), excimer laser annealing (“ELA”), metal-induced crystallization (“MIC”), metal-induced lateral crystallization (“MILC”) or sequential lateral solidification (“SLS”), may be used as a crystallization method of amorphous silicon. In an exemplary embodiment, where the crystallization methods is applied to the substrate described above, the crystallization methods may be a method that may be performed without a high-temperature heating process.

In one exemplary embodiment, for example, the crystallization may be performed by a low-temperature polysilicon (“LTPS”) process, and the activation of the active layer 412 may be performed by irradiation with a laser beam in a short period of time, and thus, an entire process may be performed at about 300° C. or less, thereby effectively preventing the exposure of the substrate 310 at a high temperature above about 300° C. In such an embodiment, the second transistor TR2 may be disposed on the substrate 310 including a polymer material.

In an exemplary embodiment, a source portion 412b and a drain portion 412a are formed in the active layer 412 by doping with N-type or P-type impurity ions. A portion between the source portion 412b and the drain portion 412a is a channel portion 412c that is not doped with an impurity.

A gate dielectric layer 313 is disposed on the active layer 412. The gate dielectric layer 313 may have a single layer structure of SiO₂ or a double layer structure of SiO₂ and SiNₓ.

A gate electrode 414 is disposed on a predetermined portion of the gate dielectric layer 313. The gate electrode 414 is connected to a gate line (not shown), via which on/off signals are applied to a thin film transistor. The gate electrode 414 may include a single conductive layer or multiple conductive layers.

A drain electrode 416a and a source electrode 416b are disposed on are formed on the gate electrode 414. In such an embodiment, the drain electrode 416a and the source electrode 416b are respectively connected to the source portion 412b and the drain portion 412a of the active layer 412, interposing an interlayer dielectric 315 disposed therebetween. The interlayer dielectric 315 may include an insulating material, such as SiO₂ and SiNₓ, for example. The interlayer dielectric 315 may include an insulating organic material.

A pixel-defining layer 318 is disposed on the interlayer dielectric 315 to cover the drain electrode 416a and the source electrode 416b. A pixel electrode 314 including substantially the same transparent conductive material as the gate electrode 414 may be disposed on the buffer layer 311 and the gate dielectric layer 313. Resistances of the drain electrode 416a and the source electrode 416b may be lower than the resistance of the gate electrode 414.

The pixel electrode 314 may include a metal with a low work function, e.g., Li, Ca, LiF/Ca, LiF/Al, Al, Mg, and a compound thereof, deposited on the gate dielectric layer 313, and an auxiliary electrode including a material of a transparent electrode, such as indium tin oxide (“ITO”), indium zinc oxide (“IZO”), ZnO and In₂O₃, disposed on the deposited metal. The pixel electrode 314 is not limited thereto and may be a reflective electrode in an alternative exemplary embodiment.

The intermediate layer 319 is disposed on the pixel electrode 314. In an exemplary embodiment, intermediate layer 319 may be provided on the pixel electrode by etching a portion of the pixel-defining layer 318. The intermediate layer 310 includes at least an organic light-emitting layer that emits visible light.

A counter electrode 320 is disposed on the intermediate layer 319 as a common electrode. In such an embodiment, voltages having different polarities are applied to the intermediate layer 319 to emit light from the intermediate layer 319.

The organic light-emitting layer of the intermediate layer 319 may include a low molecular weight organic material or a polymer organic material. In an exemplary embodiment, where the organic light-emitting layer of the intermediate layer 319 includes a low molecular weight organic material, the intermediate layer 319 may include a hole injection layer (“HIL”), a hole transport layer (“HTL”), an emissive layer (“EML”), an electron transport layer (“ETL)”, or an electron injection layer (“EIL”), which are stacked in a single or composite structure.

In an exemplary embodiment, the intermediate layer 319 may include copper phthalocyanine (“CuPc”), N,N′-di(naphthalene-1-yl)-N,N′-diphenyl-benzidine (“NPB”), or tris-8-hydroxyquinoline aluminum (“Alq3”). In such an embodiment, the intermediate layer 319 may be provided by a method such as vacuum deposition of such a low molecular weight organic material using a mask.

In an exemplary embodiment, where the organic light-emitting layer of the intermediate layer 319 includes a polymer organic material, the intermediate layer 319 may have a structure including an HTL and an EML. In such an embodiment, the HTL may include poly(ethylenedioxythiophene) (“PEDOT”), and the EML may include a polymer organic material, such as poly(phenylenevinylenes) (“PPVs”) and polyfluorenes. In such an embodiment, where the organic light-emitting layer of the intermediate layer 319 includes the polymer organic material, the organic light-emitting layer of the intermediate layer 319 may be provided by screen printing or inkjet printing.

The intermediate layer 319 is not limited thereto the exemplary embodiment described above, and may be variously modified.

The counter electrode 320 may include a transparent electrode or a reflective electrode.

In an exemplary embodiment, where the counter electrode 320 includes the transparent electrode, the counter electrode 320 may include a metal with a low work function, e.g., Li, Ca, LiF/Ca, LiF/Al, Al, Mg, and a compound thereof, deposited on the intermediate layer 319, and an auxiliary electrode including a material of the transparent electrode, such as ITO, IZO, ZnO and In₂O₃, disposed on the deposited metal.

In an exemplary embodiment, where the counter electrode 320 includes the reflective electrode, the counter electrode 320 may be provided by depositing Li, Ca, LiF/Ca, LiF/Al, Al, Mg, and a compound thereof on an entire surface of the display portion.

When the transparent electrode or the reflective electrode is used as the pixel electrode 314, the pixel electrode 314 may be formed in a shape corresponding to the form of an opening of each sub-pixel. The counter electrode 320 may be formed by deposition of the transparent electrode or the reflective electrode on substantially an entire surface of the display area, but not being limited thereto. In an alternative exemplary embodiment, the counter electrode 320 may be formed in various patterns. In such an embodiment, the pixel electrode 314 and the counter electrode 320 may be disposed to face each other.

In an exemplary embodiment of the organic light-emitting display apparatus, the pixel electrode 314 is an anode and the counter electrode 320 is a cathode, but not being limited thereto.

FIG. 8 is a schematic exploded perspective view of an alternative exemplary embodiment of a film 500 for a display apparatus, according to the invention.

As illustrated in FIG. 8, an alternative exemplary embodiment of the film 500 for a display apparatus includes a first thin film 510 including at least one of an organic material and an inorganic material, a metal thin film 520 in contact with a first portion of a surface of the first thin film 510, and a second thin film 530 in contact with a second portion of the surface of the first thin film 510, in which the metal thin film 520 is not formed. In such an embodiment, the first thin film 510, the metal thin film 520 and the second thin film 530 are substantially the same as the first thin film 110, the metal thin film 120 and the second thin film 130 of the exemplary embodiment shown in FIG. 1 except that the first thin film 510 is disposed under the metal thin film 520 and the second thin film 530, and except for a shape of the metal thin film 520 and a contact position between the metal thin film 520 and the first thin film 510, and a shape of the second thin film 530 and a contact position between the second thin film 530 and the first thin film 510.

In such an embodiment, the first thin film 510 may include an inorganic material, such as silicon oxide or silicon nitride, for example. In an alternative exemplary embodiment, the first thin film 510 may include an organic material, such as epoxy and polyimide, for example. In an exemplary embodiment, the first thin film 510 may have a structure in which an organic material and an inorganic material are alternatingly deposited, but the invention is not limited thereto. A thickness of the first thin film 510 may be less than about 10 times a wavelength in the wavelength range of visible light. In one exemplary embodiment, for example, the thickness of the first thin film 510 may be in a range of about 10 nm to about 5,000 nm.

The metal thin film 520 may include a metal, such as Ag, Mg, Al, Pt, Pd, Au, Ni, Nd, Ir, Cr, Li or Ca, for example. A thickness of the metal thin film 520 may be less than a wavelength in the wavelength range of visible light. In one exemplary embodiment, for example, the thickness of the metal thin film 520 may be in a range of about 5 nm to about 500 nm.

The second thin film 530 may include a material having low adhesion to the metal thin film 520. In such an embodiment, adhesion between the metal thin film 520 and the second thin film 530 may be lower than adhesion between the metal thin film 520 and the first thin film 510. In one exemplary embodiment, for example, the second thin film 530 may include at least one of 8-quinolinolato lithium,
N,N-diphenyl-N,N-bis(9-phenyl-9H-carbazol-3-yl)biphenyl-4,4′-diamine,
N (di phenyl-4-yl)9,9-dimethyl-N-(4(9-phenyl-9H-carbazol-3-yl)phenyl)-9H-fluorene-2-amine, and
2-(4-(9,10-di(naphthalene-2-yl)anthracene-2-yl)phenyl)-1-phenyl-1H-benzo-[D]imidazole.

In such an embodiment, the second thin film 530 may be disposed on the same layer as the metal thin film 520, and a thickness of the second thin film 530 may be substantially the same as the thickness of the metal thin film 520. In one exemplary embodiment, for example, the thickness of the second thin film 530 may be less than a wavelength in the wavelength range of visible light.

The first thin film 510, the metal thin film 520 and the second thin film 530 may collectively define a unit film 500a, and the film 500 for a display apparatus may include a plurality of unit films 500a. In such an embodiment, the film 500 for a display apparatus may be provided by stacking the unit film 500a multiple times. In an exemplary embodiment of the film 500 for a display apparatus, as shown in FIG. 8, three unit films 500a are stacked on one another, but the invention is not limited thereto. In an alternative exemplary embodiment, two or more than three unit films 500a may be stacked in the film 500 for a display apparatus. In such an embodiment, 10 or less unit films 500a may be stacked in the film 500 for a display apparatus such that a thickness of the film 500 may be less than a predetermined thickness.

The film 500 for a display apparatus may further include a third thin film 550 on the second thin film 530 and the metal thin film 520. The third thin film 550 may include substantially the same material as the first thin film 510, and a thickness of the third thin film 550 may be substantially the same as the thickness of the first thin film 510.

In an exemplary embodiment, light reflectance of a first portion of the film 500 for a display apparatus, in which the first thin film 510, the metal thin film 520 and the third thin film 550 overlap each other, is relatively low, and light transmittance of a second portion of the film 500 for a display apparatus, in which the first to third thin films 510, 530 and 550 overlap each other, is relatively high. In such an embodiment, the light reflectance of the first portion of the film 500 for a display apparatus may be lower than the light reflectance of the second portion of the film 500 for a display apparatus, and the light transmittance of the second portion of the film 500 for a display apparatus may be higher than the light transmittance of the first portion of the film 500 for a display apparatus. In such an embodiment, destructive interference may occur in waves incident on the first thin film 510 and the metal thin film 520, light absorption due to surface plasmon may occur at an interface between the first thin film 510 and the metal thin film 520 or the third thin film 550 and the metal thin film 520. In such an embodiment, the first to third thin films 510, 530 and 550 are transparent, and light absorption thereof is thereby low such that the second portion has a substantially high light transmittance.

In an exemplary embodiment, the arrangement between the metal thin film and the second thin film may be changed based on the characteristics of the display apparatus.

The invention is amenable to various modifications and alternative forms that depart from the exact specifics shown by way of example in the drawings and the particular embodiments described above. It should be understood, however, that the intention is not to limit the invention to the particular embodiment described. On the contrary, the invention is to cover all modifications, equivalents, and alternatives falling within the spirit and scope of the invention as defined by the appended claims.

What is claimed is:

1. A film for a display apparatus, the film comprising:
a first thin film comprising at least one of an organic material and an inorganic material;
a metal thin film in contact with a first portion of a surface of the first thin film; and
a second thin film in contact with a second portion of the surface of the first thin film, which is different from the first portion.

2. The film for a display apparatus of claim 1, wherein adhesion between the metal thin film and the second thin film is lower than adhesion between the metal thin film and the first thin film.

3. The film for a display apparatus of claim 1, comprising:
a plurality of unit films stacked on one another, wherein each of the unit films comprises the first thin film, the metal thin film and the second thin film.

4. The film for a display apparatus of claim 1, wherein the metal thin film comprises at least one of magnesium and silver.

5. The film for a display apparatus of claim 1, wherein the second thin film comprises at least one of 8-quinolinolato lithium,
N,N-diphenyl-N,N-bis(9-phenyl-9H-carbazol-3-yl)biphenyl-4,4′-diamine,
N (di phenyl-4-yl)9,9-dimethyl-N-(4(9-phenyl-9H-carbazol-3-yl)phenyl)-9H-fluorene-2-amine, and
2-(4-(9,10-di(naphthalene-2-yl)anthracene-2-yl)phenyl)-1-phenyl-1H-benzo-[D]imidazole.

6. The film for a display apparatus of claim 1, wherein a thickness of the metal thin film is less than a wavelength in a wavelength range of visible light.

7. The film for a display apparatus of claim 6, wherein the thickness of the metal thin film is in a range of about 5 nanometers to about 500 nanometers.

8. The film for a display apparatus of claim 1, wherein a thickness of the first thin film is smaller than about 10 times a wavelength in a wavelength range of visible light.

9. The film for a display apparatus of claim 8, wherein the thickness of the first thin film is in a range of about 10 nanometers to about 5,000 nanometers.

10. The film for a display apparatus of claim 1, wherein light reflectance of a portion, in which the first thin film and the metal thin film overlap each other, is lower than light reflectance of a portion, in which the first thin film and the second thin film overlap each other.

11. The film for a display apparatus of claim 1, wherein light transmittance of a portion, in which the first thin film and the second thin film overlap each other, is higher than light transmittance of a portion in which the first thin film and the metal thin film overlap each other.

12. The film for a display apparatus of claim 1, wherein the metal thin film is disposed in a center portion of the first thin film.

13. The film for a display apparatus of claim 1, further comprising:
a third thin film disposed opposite to the first thin film, wherein the metal thin film and the second thin film are disposed between the first thin film and the third thin film.

14. An organic light-emitting display apparatus comprising:
a substrate;
an organic light-emitting unit disposed on the substrate; and
a film disposed on the substrate,
wherein the film comprises:
a first thin film comprising at least one of an organic material and an inorganic material;
a metal thin film in contact with a first portion of a surface of the first thin film; and
a second thin film in contact with a second portion of the surface of the first thin film, which is different from the first portion.

15. The organic light-emitting display apparatus of claim 14, wherein adhesion between the metal thin film and the second thin film is lower than adhesion between the metal thin film and the first thin film.

16. The organic light-emitting display apparatus of claim 14, wherein the film comprises a plurality of unit films stacked on one another, wherein each of the unit films comprises the first thin film, the metal thin film and the second thin film.

17. The organic light-emitting display apparatus of claim 14, wherein the metal thin film comprises at least one of magnesium and silver.

18. The organic light-emitting display apparatus of claim 14, wherein the second thin film comprises at least one of 8-quinolinolato lithium,
N,N-diphenyl-N,N-bis(9-phenyl-9H-carbazol-3-yl)biphenyl-4,4′-diamine,
N(diphenyl-4-yl)9,9-dimethyl-N-(4(9-phenyl-9H-carbazol-3-yl)phenyl)-9H-fluorene-2-amine, and
2-(4-(9,10-di(naphthalene-2-yl)anthracene-2-yl)phenyl)-1-phenyl-1H-benzo-[D]imidazole.

19. The organic light-emitting display apparatus of claim 14, wherein a thickness of the metal thin film is less than a wavelength in a wavelength range of visible light.

20. The organic light-emitting display apparatus of claim 14, wherein light reflectance of a portion, in which the first thin film and the metal thin film overlap each other, is lower than light reflectance of a portion, in which the first thin film and the second thin film overlap each other.
